(19) United States
(12) Patent Application Publication
(10) Pub. No.: US 2005/0047276 A1
(43) Pub. Date: Mar. 3, 2005

(54) ULTRASONIC BEAMFORMER AND CORRELATOR

(76) Inventors: Walter Guy Scott, North Palm Beach, FL (US); Rainer R. Schmitt, Palm Beach Gardens, FL (US); Richard D. Irving, Palm Beach Gardens, FL (US)

Correspondence Address: MALIN HALEY AND DIMAGGIO, PA, 1936 S ANDREWS AVENUE, FORT LAUDERDALE, FL, 33316, US

(21) Appl. No.: 10/710,831

(22) Filed: Aug. 5, 2004

Related U.S. Application Data
(60) Provisional application No. 60/492,512, filed on Aug. 5, 2003.

(51) Int. Cl. H03K 17/693; G01S 15/00; G06F 17/50; G01N 29/04

(52) U.S. Cl. 367/87; 73/618

(57) ABSTRACT

A printed circuit board that performs as an ultrasonic beamformer and a correlator that includes an advanced correlation algorithm that greatly reduces the cost of correlation especially useful for ultrasonic imaging and medical imaging. The algorithm uses three simultaneous cross-correlators to sweep down the acoustic line making correlation results at each step. One correlator

### BACKGROUND OF INVENTION

Field of the Invention

This invention relates to a printed circuit board that performs as an ultrasonic beamformer and a correlator that can be used alone or in multiples for medical or sonar imaging. The invention involves advances from implementing algorithms into the hardware.

2. Description of Related Art

A real-time correlator requires may fast multipliers working in parallel to obtain preferably a normalized Sum of the Products (SOP) at the same speed as the beamformer output clock (40-60 MHz). Winprobe has been designing correlators with Xilinx FPGA″s making each fast 16-bit multiplier out of 25,000 gates. In December of 2000, Xilinx Corporation made available the Virtex II series of FGPA chips that contain up to 10 million gates and 200 hardware 18×18 bit fast multipliers. The real benefit of these chips is the interconnectivity so signals can be directed to various filters without limitation or delay jitter. The 2-6 million gate chips chosen by Winprobe for this design can have their 10 million bits of configuration programming loaded from a PC through a USB2 interface in two seconds in the field.

This project will start with the current board that contains 32 independently programmable transmit and receive channels, all support circuitry and two milti-million gate FPGA″s. They are nominally designated as the beamformer/scan converter FPGA and the Correlator FPGA, but they can be programmed with any multiple of tasks. Ten boards will be required to implement a 320-channel system (5 elevations of 64 channel phased arrays). The board is capable of producing 3 simultaneous receive lines from each transmit beam. The Correlator is capable of collecting data from the other boards to in concert produce 9 simultaneous receive beams covering the lateral and elevation dimensions. At the date of this proposal not all FPGA code has been written or evaluated.

Up to 18 bits of data from a beamformer can be input into the correlator chip, at least 60 MHz, where the RF line of up to 8000 points can be cross-correlated against previous or simultaneously acquired lines with the Sum of the Products or the normalized SOP being computed and delivered at the input frequency (60 MHz). At least 27 of these SOP″s with their associated algorithms may reside within each chip. The current associated algorithm is: peak detection to 1/256^{th} of a clock pulse (complete system evaluation is required to see what level of accuracy is practically attainable in a real word noisy environment). Anticipated medical algorithms are: normalization, stress and elasticity.

Earlier this year, a realization occurred that allowed what we call the Winprobe Advanced Correlation Algorithm (WACA) that obsoletes all previous work by reducing the cost of cross correlation by a factor of 30.

The current state of the published art is as in FIG. 1 from the work of Duke University where the ensemble is tracked using 2:1 parallel receive: “an ensemble of two beam line sets is acquired along a given steering direction. A kernel segment from beam 1 (K₁) is tracked within the search segments in beam 1(S₁) and beam 2(S₂) using a SAD algorithm.”

### BRIEF DESCRIPTION OF DRAWINGS

FIG. 1 shows the state of published art in a schematic diagram showing an ensemble of two beam line sets acquired along a given steering direction.

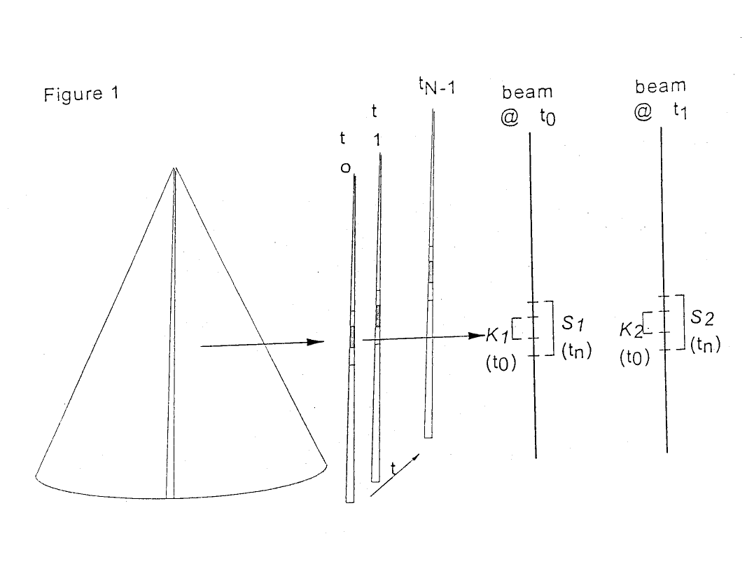

FIG. 2 shows a schematic diagram of a conventional cross-correlation engine with two beams: T₀ and T₁.

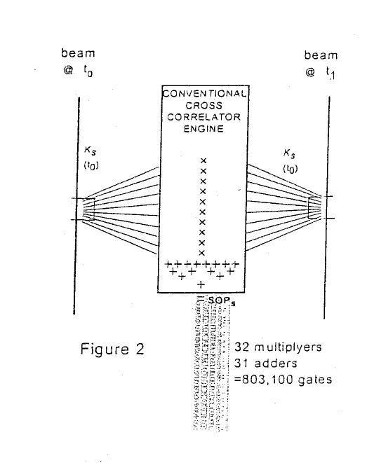

FIG. 3 shows a schematic diagram of the present invention using three cross-correlator engines.

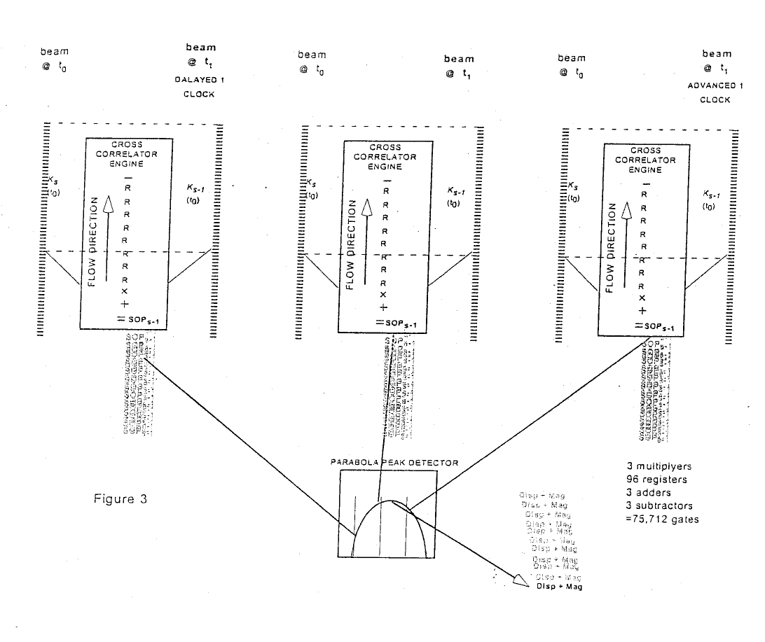

FIG. 4 shows a schematic diagram of nine beam of cross-correlations 27cc magnitudes of target.

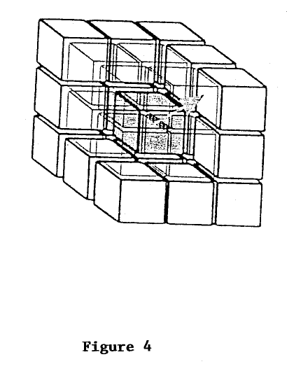

### DETAILED DESCRIPTION

An ultrasonic scanning apparatus for imaging that allows the three dimensional displacement vector of a backscatterer imaging device to be estimated from the backscatter from partially overlapping beams that are cross-correlated in multiple cross-correlators instantiated in a field programmable gate array or application specific integrated circuit especially useful in medical imaging. The cross-correlation may be formed by an algorithm wherein the elements (data points) of the kernel in one beam are used with the elements (data points) from the kernel in a second beam in such a fashion that both kernels are not shifted over each other but are shifted together on each clock pulse.

The Sum of the Absolute Differences Algorithm is chosen because it is a far less computationally intensive algorithm than a true cross-correlation (normalized SOP). Most state of the art correlators uses SAD for this reason but it has significant compromises. As a best match is approached, the SAD tends to zero so by taking the values around the match to interpolate sub-clock match locations, the statistical data is poor. In an SOP algorithm, the match is at the peak of a parabola where, for example, 32 samplings kernel of 16 bits per sampling at half average intensity has a parabola peak value of 32 billion that provides excellent statistics for sub-clock match estimation.

To make a SOP engine of kernel length 32 requires 32 16 bit fast multipliers that feed an adder funnel.

In the field of ultrasound cross-correlation imaging in the human body, the two beams that are cross-correlated may be acquired with less than 200 microseconds temporal separation. A volume of blood or tissue moving at 10 cm/sec would move 20 microns in 200 us. This 20 microns is the distance sound will travel between one beamformer ADC clock samplings at 40 MHz. A few elements of the human body move faster than 10 cm/sec and we will show later how the faster velocities may be simply accommodated. Initially, we may assume that under the above conditions, the shift or best kernel match will occur within plus or minus 1 clock shift. Thus, if we correlate the kernel of line t₀ against the range in line t₁ and restrict the search range to one point behind and one in front, the process is classic correlation. We may now process the three correlations simultaneously and a extraordinary simplification occurs.

The Advanced Winprobe Cross-Correlator engine (AWCC) concept works initially on the assumption that many cross-correlators are available so the fastest way to search for a point of best match is to use in the simplest case 3 simultaneous cross-correlators to sweep down the acoustic line making correlation results at every step. One correlator is set in front, one at the correlated point and one behind. The three SOP results (either normalized or not) are sent at every clock to a peak detector algorithm that will output the displacement and magnitude for every clock.

There is now a significant computational advantage for each SOP engine. As the stream of data points from the kernel in beam t₀ is multiplied by the data points from the kernel in beam t₁, the kernels are not shifted over each other but shifted together on each clock pulse so all the multiplications except the new one are already done thus only one multiplier is needed and the kernel of multiplicands is kept as a sum where the new multiplicand is added and the last is subtracted on each clock. The smallest FPGA (XC2V2000) could not support 56 cross-correlators in the one chip. A further anticipated advantage of this design is that the kernel can be any length and this length can be a variable able to be changed in a few microseconds. A short length (˜20 samples) would be expected to perform better than a longer one if any velocity gradients are present. As implementing a triple cross-correlator is not a burden, multiple lengths could be run simultaneously and any loss of correlation due to a velocity gradient will be estimated from the loss of magnitude output by the peak detector. The internal speed of the FPGA allows the correlation function to run at 180 MHz while the beamformer will, in most cases, provide data at less than 60 MHz allowing each correlator to be run three times with different kernel lengths giving insights to any cause of de-correlation. Preliminary design has also begun on an interpolation engine so the RF data can be re-sampled at slightly higher and lower frequencies. These re-sampled RF vectors will then be applied to the AWCC engine to estimate the strain in the kernel.

The algorithms described above have found a cross-correlation on every clock that is the shift of the voxel down the beam (˜2-microns). We could not possible display this amount of data and as a voxel will probably comprise of 32 digitizations, we can use this over-sampling of the correlators to reduce noise in an elegant averaging algorithm.

For the case there the region contains elements moving faster than 10 cm/second; a) the forward and back cross-correlators could be set several clock pulses apart; b) the sampling frequency could be reduced by discarding every second digitization; c) additional correlators could be added at +/−2, 3 and 4 clocks and multiple peak detectors used. Thus, for blood flow in the ascending aorta at three meters per second and a 40 MHz clock, the separation would be +/− 12 clocks. This over run condition is easily detected as no peak is detected between the in front and behind correlator values. Running multiple sets of triple correlators will assist in removing any false peaks that could be represent in on set.

The task is defined as cross-correlating the backscatter signature from every voxel (target) in a center beam at time t₀ with the 27 voxels that surround the target from the nine beams at time t₁. This will require 27 cross correlators each in the advanced correlator design consisting of three cross-correlator engines. Plus any engines in the axial direction required to account for velocities faster than 10 cm/sec if we program all the offsets to one clock for accuracy. A typical over-redundant configuration would be 99 engines. Each FPGA will support 56 engines easily and there are 10 FPGAs on the ten boards devoted to this task.

Additional engines would, in some circumstances, be used to create the next t₀ line from the advancing edge in the lateral direction for the next beam to increase the frame rate to the full acquisition speed of the beamformer.

Upon acquisition of the initial nine beams at t₀, the cross-correlations would be performed and though no flow would be obtained, the 27 correlation magnitudes would be stored for comparison with the 27 CC magnitudes of the target at t₀ against the neighborhood at t₁ to estimate decorrelation rate which could be due to turbulence or velocity gradients and require the kernels to be shortened which eventually could be automatic.

Let us examine cross-correlation of a line of say 1000 elements against another line of 1000 elements with a kernel of 32 elements.

Case A: Conventional Correlation with no a priori assumptions. The thirty-two elements of kernel the line at T₀ are multiplied by the first thirty-two elements of line at and the SOP is normalized requiring thirty-two multiplies. The target is then moved down in the range of T₁ and the process repeated for each of the 1000-32 increments. This process requires 32,000 multiplies. The kernel is then incremented down one element and the process is repeated.

The correlation of T₀ against T₁ thus requires 32,000,000 multiplies.

Case B: Conventional Correlation with assumptions of the possible (small) shift. The thirty-two elements of kernel the line at T₀ are multiplied by the first thirty-two elements of line T₁ and the SOP is normalized requiring thirty-two multiplies. The target is then moved down in the range of T₁ and the process repeated for each of the elements in the selected range. Let us assume the smallest range of three to cover any small forward or backward movement. This process requires 96 multiplies. The kernel is then incremented down one element and the process is repeated. The correlation of T₀ against T₁ thus requires 96,000 multiplies.

Case C: Advanced Winprobe Cross-Correlator. The first element of the kernel in the line at T₀ are multiplied by the first element of line T₁ and added to a register. The second . . . third . . . and finally the thirty-second elements multiplies and added to the register. This is the SOP of the first available kernel. Then, the thirty-third elements of both T₀ and T₁ are multiplied and the product added to the register and the product of the first elements of is subtracted T₀ and T₁ from the register. This is the second SOP. Then, the thirty-forth and ongoing SOP″s are found until the end of the lines are reached. In this way, the SOP of two lines is reached with only 1000 multiplies. This in itself only tells us how good the match was between a line T₀ and a line T₁ that was. Now if we did the process with T₁ offset from by +one element and again with T₁ offset by one element we could estimate the shift of all the elements in line T₀ to line T₁. This is the same results as case A and B but with only 3000 multiplies. If the three cross-correlations are performed simultaneously, the peak of the shift can be estimated on each shift and the SOPs discarded further reducing the circuitry and giving real time cross-correlation. One multiplier, a shift register and an adder and subtractor form one cross-correlator which may be budgeted as 75,000+512+100+100 gates whereas the traditional correlator requires 32 multipliers and 63 adders which requires 800,000+3100 gates.

The instant invention has been shown and described herein in what is considered to be the most practical and preferred embodiment. It is recognized, however, that departures may be made therefrom within the scope of the invention and that obvious modifications will occur to a person skilled in the art.

1. An ultrasonic scanning apparatus wherein:
the three-dimensional displacement vector of a backscatterer is estimated from the backscatter from partially overlapping beams cross-correlated in multiple cross-correlators instantiated in a field programmable gate array or application specific integrated circuit.

2. The apparatus of claim 1, wherein:
the cross-correlation is formed by an algorithm wherein the elements (data points) of the kernel in one beam are used with the by the elements (data points) from the kernel in a second beam in such a fashion that both kernels are not shifted over each other but are shifted together on each clock pulse.

3. The apparatus of claim 2, wherein:
multiple cross-correlation sub-results are attained by a plurality of beam pairs.

4. The apparatus of claim 3, wherein:
26 cross-correlation sub-results are attained from one acoustic transmission with nine simultaneous, adjacent in three-dimensions, receive breams to estimate the flow of the backscatterers in three dimensions.
